(19) United States
(12) Patent Application Publication
(10) Pub. No.: US 2004/0232434 A1
(43) Pub. Date: Nov. 25, 2004

(54) Electroluminescent lamp

(75) Inventor: Chang-Hong Chen, Taipei (TW)

Correspondence Address: BACON & THOMAS, PLLC, 625 SLATERS LANE, FOURTH FLOOR, ALEXANDRIA, VA, 22314

(73) Assignee: YEN TSENG TECHNOLOGY CORPORATION, Tu Cheng City (TW)

(21) Appl. No.: 10/442,097

(22) Filed: May 21, 2003

(51) Int. Cl. H01L 33/00

(52) U.S. Cl. 257/99; 257/100

(57) ABSTRACT

An electroluminescent lamp is constructed to include an electroluminescent panel adapted to emit light when excited by an electric voltage, a transparent shell injection-molded from plastics on the electroluminescent panel in the shape of a wall lamp, floor tile, or wall plate for wall switch/socket, and a power input device extended from the electroluminescent panel to the outside of the shell for receiving external power supply to excite the electroluminescent panel.

### BACKGROUND OF THE INVENTION

(a) Field of the Invention

The present invention relates to an electroluminescent lamp and, more particularly, to such an electroluminescent lamp, which comprises a transparent plastic shell and an electroluminescent lamp embedded in the shell.

(b) Description of the Prior Art

An electroluminescent lamp is an electronic light-emitting device that does not produce heat when emitting light. An electroluminescent lamp has a long service life. However, the brightness of an electroluminescent lamp reduces gradually with its use due to the interference of outside moisture or pollutant. When using an electroluminescent lamp as a wall lamp or wall plate for wall socket/switch, a frame shall be used to house the electroluminescent lamp. However, the frame cannot protect the electroluminescent lamp against outside moisture and pollutant. Further, the exposed design of an electroluminescent lamp tends to be damaged or scrapped by an external object, and an electric shock may occur when a person touched the wires of the electroluminescent lamp accidentally.

### SUMMARY OF THE INVENTION

The present invention has been accomplished under the circumstances in view. According to one aspect of the present invention, the electroluminescent lamp comprises an electroluminescent panel adapted to emit light when excited by an electric voltage, a transparent shell injection-molded from plastics on the electroluminescent panel in the shape of a wall lamp, floor tile, or wall plate for wall switch/socket, and a power input device extended from the electroluminescent panel to the outside of the shell for receiving external power supply to excite the electroluminescent panel. According to another aspect of the present invention, the power input device can be comprised of two electric wires or two metal plug blades electrically connected to the electroluminescent panel and extended out of the shell. According to still another aspect of the present invention, the shell can be made in the shape of a wall lamp, a floor tile, or a wall plate for wall switch/wall socket.

### BRIEF DESCRIPTION OF THE DRAWINGS

FIG. 1 is an elevational view of an electroluminescent panel for an electroluminescent lamp according to the present invention.

FIG. 2 is a sectional view of the electroluminescent lamp according to the present invention, showing the electroluminescent panel embedded in the shell.

FIG. 3 is a perspective view of the present invention, showing the electroluminescent lamp made in the form of a wall lamp.

FIG. 4 is a sectional side view of the electroluminescent lamp shown in FIG. 3.

FIG. 5 is a schematic drawing showing the electroluminescent lamp used as the wall plate of a wall switch according to the present invention.

FIG. 6 is a schematic drawing showing the electroluminescent lamp used as the wall plate of a wall socket according to the present invention.

FIG. 7 is a sectional view of FIG. 5.

FIG. 8 is a schematic drawing showing different application examples of the present invention.

FIG. 9 is a schematic drawing showing the electroluminescent lamp used as an exit floor tile according to the present invention.

FIG. 10 is a sectional view in an enlarged scale of a part of FIG. 9.

### DETAILED DESCRIPTION OF THE PREFERRED EMBODIMENTS

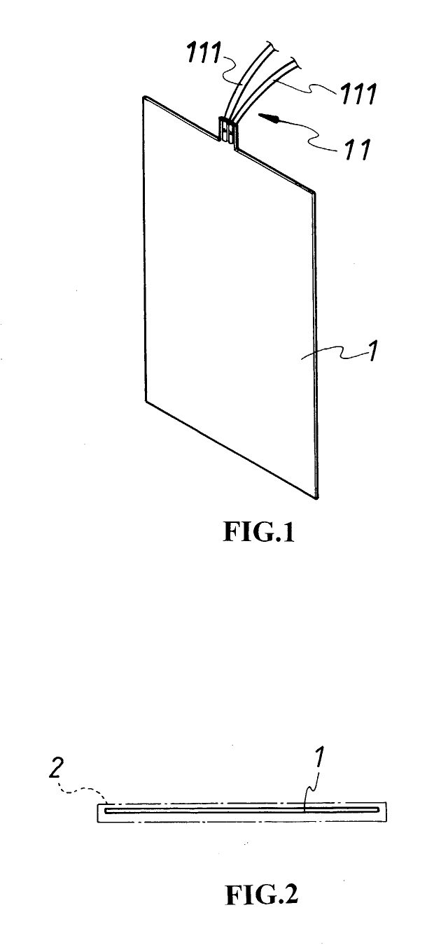

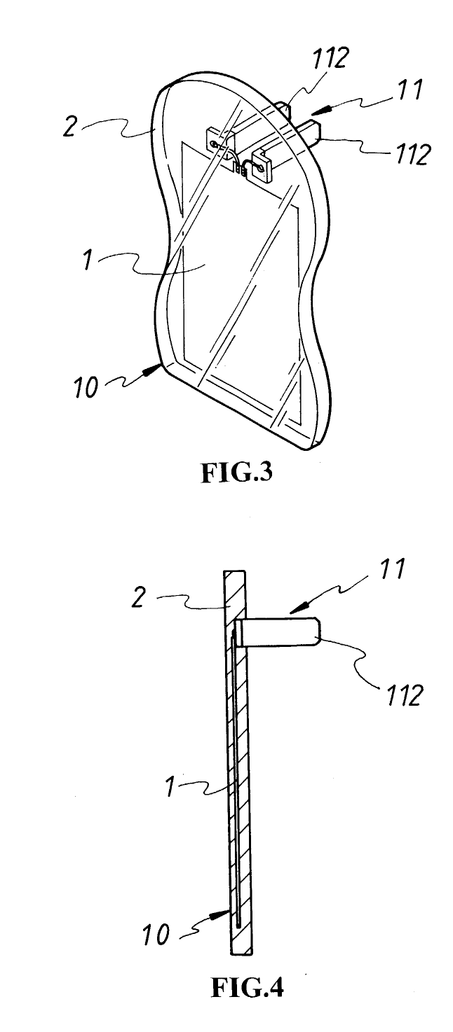

Referring to FIGS. 1 and 2, an electroluminescent lamp in accordance with the present invention is shown comprised of an electroluminescent panel 1 and a shell 2. The electroluminescent panel 1 is generally comprised of a transparent electrode, a luminous layer, an insulative layer, and a back electrode. When AC applied to the luminous layer (electro-luminescent phosphor), electrons are excited by the electrical field generated within the phosphor powder and become highly energized. When electrons return to a stable state, light is emitted. Because the fabrication of the electroluminescent panel 1 is of the known art and not within the scope of the claims of the present invention, no further detailed description in this regard is necessary. The electroluminescent panel 1 comprises a power input device 11. The power input device 11 can be made in any of a variety of forms. The power input device 11 can be comprised of two electric wires (positive pole and negative pole electric wires) 111 as shown in FIG. 1, or two metal plug blades 112 extended out of the back side of the electroluminescent lamp as shown in FIG. 3.

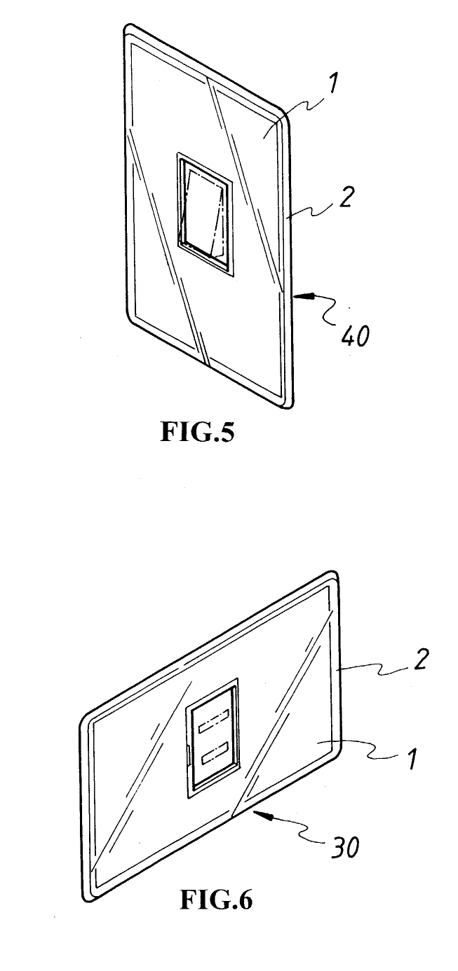

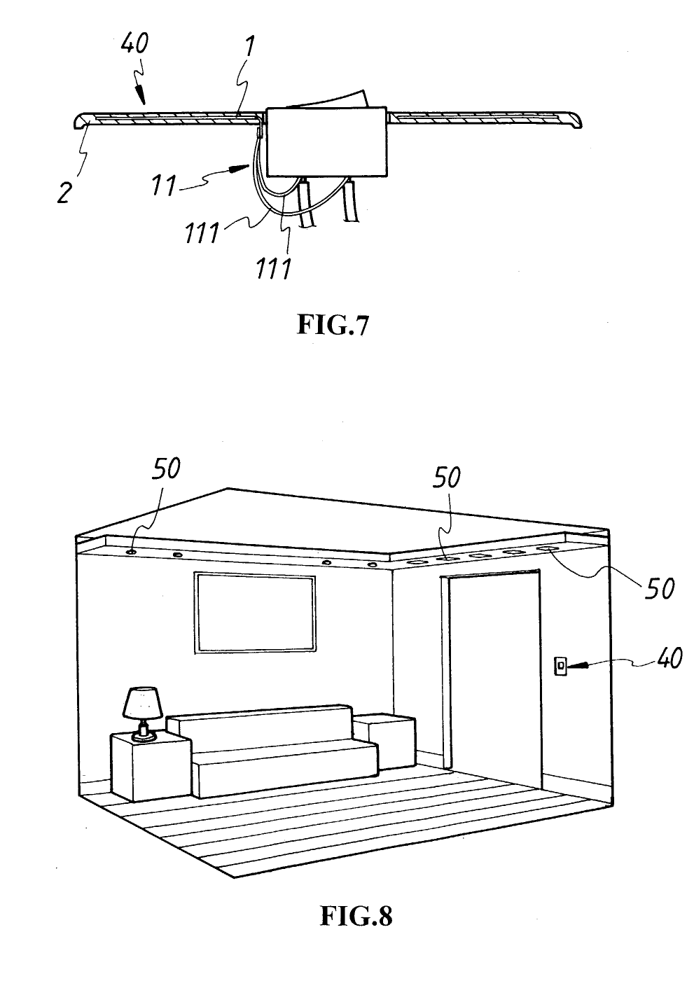

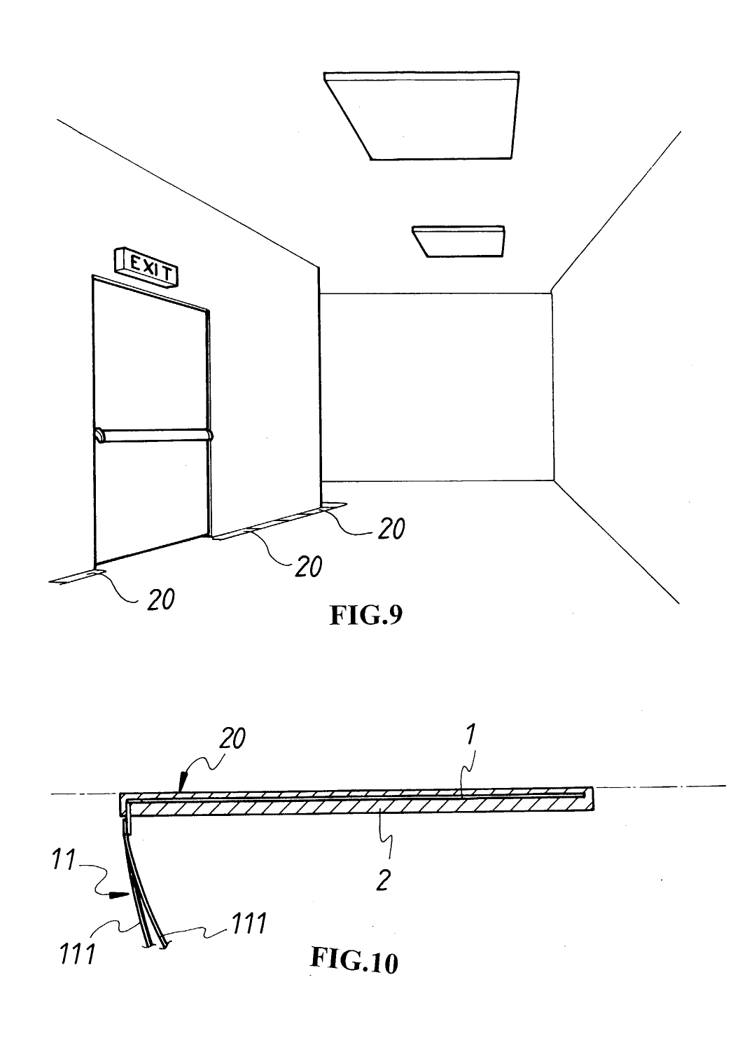

The shell 2 can be a transparent or semitransparent shell injection-molded from color or colorless plastics in any of a variety of shapes. For example, the shell 22 can be shaped like a wall lamp (night lamp) 10 (see FIGS. 3 and 4), a floor tile 20 (see FIGS. 9 and 10), a wall plate for wall socket 30 or wall switch 40 (see FIGS. 5-7), or an embedded ceiling lamp 50 (see FIG. 8).

The shell 2 is directly molded on the electroluminescent panel 1, keeping the electroluminescent panel 1 embedded therein (see FIG. 2) and the electric wires 11 or metal plug blades 112 exposed to the outside (see FIGS. 1˜4).

Because the electroluminescent panel 1 is embedded in the shell 2, the shell 2 protects the electroluminescent panel 1 from outside moisture and contamination. Therefore, outside substances do not affect the luminescence of the electroluminescent panel 1.

As indicated above, the electroluminescent lamp comprises a protective shell, an electroluminescent panel embedded in the shell, and a power input device extended from the electroluminescent panel to the outside of the protective shell for connection to power source. Further, the protective shell can be made in any of a variety of shapes, for example, the shape of a wall light, the shape of a floor tile, the shape of a wall plate for wall switch or wall socket. A prototype of electroluminescent lamp has been constructed with the features of FIGS. 1˜10. The electroluminescent lamp functions smoothly to provide all of the features discussed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. An electroluminescent lamp comprising an electroluminescent panel adapted to emit light when excited by an electric voltage, a light penetrable shell covering said electroluminescent panel, and a power input device adapted to receive external power supply for exiting said electroluminescent panel; wherein said shell is a plastic shell injection-molded from plastics on said electroluminescent panel, keeping said electroluminescent panel embedded therein and said power input device extended to the outside of said shell.

2. The electroluminescent lamp as claimed in claim 1, wherein said power input device is comprised of two electric wires electrically connected to said electroluminescent panel.

3. The electroluminescent lamp as claimed in claim 1, wherein said power input device is comprised of two metal plug blades fixedly electrically connected to said electroluminescent panel.

4. The electroluminescent lamp as claimed in claim 1, wherein said shell has the shape of a wall lamp.

5. The electroluminescent lamp as claimed in claim 1, wherein said shell has the shape of a floor tile.

6. The electroluminescent lamp as claimed in claim 1, wherein said shell has the shape of a wall plate for wall socket/switch.

7. The electroluminescent lamp as claimed in claim 1, wherein said shell is transparent.

8. The electroluminescent lamp as claimed in claim 1, wherein said shell is semitransparent.
